(19) United States
(12) Patent Application Publication
(10) Pub. No.: US 2025/0372940 A1
(43) Pub. Date: Dec. 4, 2025

(54) OPTICAL WAVEGUIDE COMPONENT

(71) Applicant: SHINKO ELECTRIC INDUSTRIES CO., LTD., Nagano (JP)

(72) Inventor: Kenji YANAGISAWA, Nagano (JP)

(21) Appl. No.: 19/215,893

(22) Filed: May 22, 2025

(30) Foreign Application Priority Data
May 28, 2024 (JP) 2024-086094

(51) Int. Cl. H01S 5/02251; H01S 3/225; H01S 5/0234; H01S 5/026

(52) U.S. Cl. CPC H01S 5/02251; H01S 5/0234; H01S 5/026; H01S 3/225

(57) ABSTRACT

An optical waveguide component includes a first support member having a first surface. The first surface includes multiple recesses. The optical waveguide component further includes an optical waveguide supported by the first support member. The optical waveguide includes a first core. The first core has a first end face exposed on the first surface.

### CROSS-REFERENCE TO RELATED APPLICATION

This application is based upon and claims priority to Japanese Patent Application No. 2024-086094, filed on May 28, 2024, the entire contents of which are incorporated herein by reference.

### FIELD

A certain aspect of the embodiment discussed herein is related to optical waveguide components.

### BACKGROUND

Various techniques for optically coupling an optical fiber to an optical waveguide provided on a substrate have been proposed. (See Japanese National Publication of International Patent Application No. 2022-509356, Japanese Laid-open Patent Publication No. 2018-040925, and Japanese Laid-open Patent Publication No. 2005-326602.)

### SUMMARY

According to an aspect, an optical waveguide component includes a first support member having a first surface. The first surface includes multiple recesses. The optical waveguide component further includes an optical waveguide supported by the first support member. The optical waveguide includes a first core. The first core has a first end face exposed on the first surface.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIG. 1 is a plan view of an optical waveguide component according to an embodiment;

FIG. 2 is a sectional view of the optical waveguide component according to the embodiment;

FIG. 3 is a sectional view of the optical waveguide component according to the embodiment;

FIGS. 4A through 4C are side views of an optical waveguide and a first support member, illustrating a method of forming recesses;

FIGS. 5A through 5C are sectional views of the optical waveguide and the first support member, illustrating the method of forming recesses;

FIGS. 6A through 6C are side views of a second support member, illustrating a method of forming protrusions; and

FIGS. 7A through 7C are sectional views of the second support member, illustrating the method of forming protrusions.

### DESCRIPTION OF EMBODIMENTS

As noted above, there are various techniques for coupling an optical fiber to an optical waveguide, but alignment between the optical waveguide and the optical fiber is complicated.

According to an embodiment, it is possible to facilitate alignment between an optical waveguide and an optical fiber. For example, an optical waveguide component that facilitates alignment between an optical waveguide and an optical fiber is provided.

One or more embodiments are described below with reference to the accompanying drawings. In the following, elements having substantially the same functional configuration are referred to using the same reference numerals, and duplicate description thereof may be omitted.

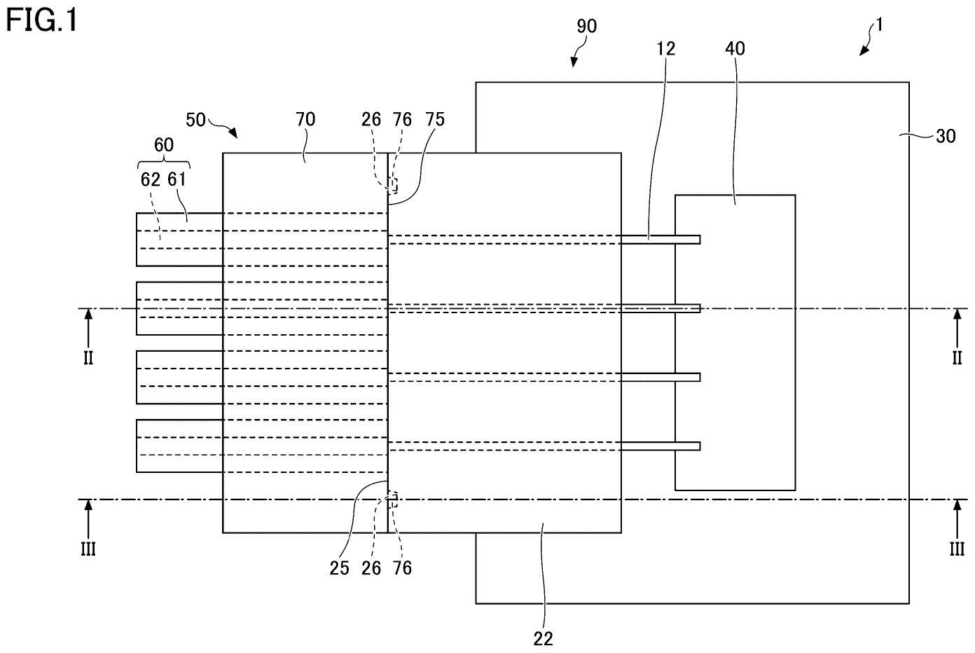

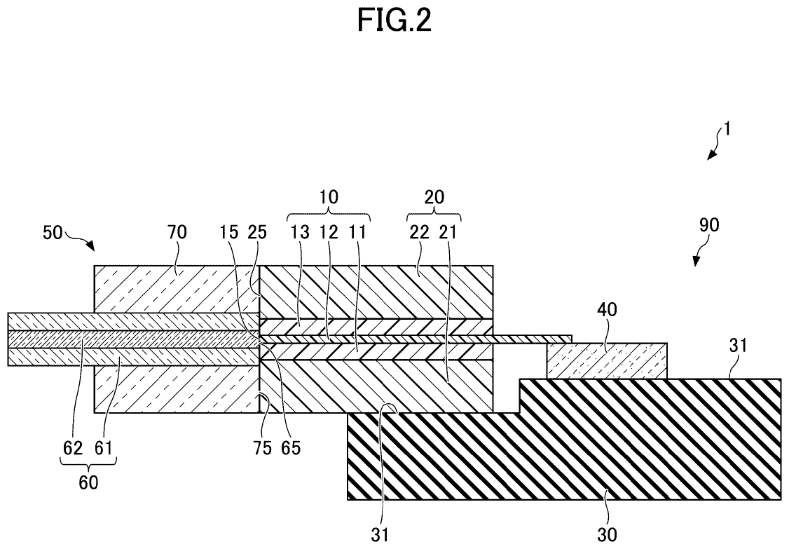

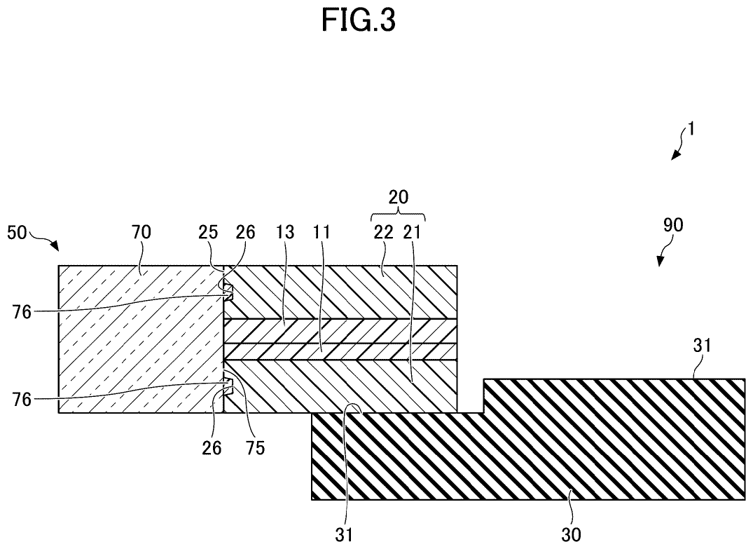

A structure of an optical waveguide component according to an embodiment is described. FIG. 1 is a plan view of the optical waveguide component according to the embodiment. FIG. 2 is a sectional view of the optical waveguide component according to the embodiment, taken along the line II-II of FIG. 1. FIG. 3 is a sectional view of the optical waveguide component according to the embodiment, taken along the line III-III of FIG. 1.

Referring to FIGS. 1 through 3, an optical waveguide component 1 according to the embodiment includes an optical waveguide substrate 90 and an optical connector 50. The optical waveguide substrate 90 includes a substrate 30, an optical waveguide 10, a first support member 20, and an optical semiconductor chip 40.

The substrate 30, which is, for example, a wiring substrate, includes wiring patterns (not depicted) and electrodes (not depicted). The first support member 20 is provided on a principal surface 31 of the substrate 30.

According to this embodiment, for convenience of description, with respect to each part or element of the optical waveguide component 1, a surface facing in the same direction as the principal surface 31 of the substrate 30 may be referred to as “upper surface,” and a surface facing in the opposite direction may be referred to as “lower surface.” The optical waveguide component 1, however, may be used in an inverted position or oriented at any angle. Furthermore, a plan view refers to a view of an object taken in a direction normal to the principal surface 31 of the substrate 30, and a planar shape refers to the shape of an object viewed in a direction normal to the principal surface 31 of the substrate 30.

The first support member 20 is fixed to the substrate 30. The first support member 20 includes a first part 21 and a second part 22. The first part 21 is fixed to the principal surface 31. For example, the first part 21 is bonded to the principal surface 31. The optical waveguide 10 is provided on the first part 21, and the second part 22 is provided on the optical waveguide 10. The optical waveguide 10 is sandwiched between the first part 21 and the second part 22. The first support member 20 is formed of, for example, organic resin. The material of the first part 21 and the second part 22 is, for example, organic resin such as epoxy resin or polyimide resin. The thickness of each of the first part 21 and the second part 22 is, for example, approximately 1 mm to approximately 2 mm.

The first support member 20 has a first surface 25. The first surface 25 is, for example, perpendicular to the principal surface 31 of the substrate 30. Recesses 26 are formed in the first surface 25. For example, multiple recesses 26 are formed in each of the first part 21 and the second part 22. For example, two recesses 26 are formed in the first part 21, and two recesses 26 are formed in the second part 22. For example, the two recesses 26 formed in the first part 21 are aligned parallel to the principal surface 31, and the two recesses 26 formed in the second part 22 are aligned parallel to the principal surface 31. Furthermore, one of the recesses 26 formed in the first part 21 and one of the recesses 26 formed in the second part 22 are aligned perpendicular to the principal surface 31, and the other of the recesses 26 formed in the first part 21 and the other of the recesses 26 formed in the second part 22 are aligned perpendicular to the principal surface 31. The recesses 26 each have a circular opening. The diameter of each recess 26 is continuously reduced toward its bottom. For example, the recesses 26 each have an inverted truncated cone shape as viewed from the first surface 25. For example, the recesses 26 each have a wall face that is inclined at approximately 7° from an axis vertical to the first surface 25. The diameter of each recess 26 at the first surface 25 is, for example, 30 μm to 200 μm. The depth of each recess 26 is, for example, 30 μm to 200 μm.

The optical waveguide 10 is supported by the first support member 20. The optical waveguide 10 includes a first cladding layer 11, core layers 12, and a second cladding layer 13. The optical waveguide 10 is a polymer waveguide. The core layers 12 are an example of “first core.”

The first cladding layer 11 is provided on the first part 21. The material of the first cladding layer 11 is, for example, organic resin such as epoxy resin or polyimide resin. The thickness of the first cladding layer 11 is, for example, approximately 10 μm to approximately 30 μm.

The core layers 12 each having a strip shape are provided on the first cladding layer 11 to extend toward the optical semiconductor chip 40. The material of the core layers 12 is, for example, organic resin such as epoxy resin or polyimide resin. For example, a sectional shape of each core layer 12 perpendicular to a direction in which the core layers 12 extend is rectangular. The core layers 12 may each have a minute sectional area to obtain a single-mode optical waveguide. The core layers 12 each have a width of 5 μm to 10 μm and a height of 5 μm to 10 μm.

The core layers 12 each have a first end face 15 exposed on the first surface 25. For example, each first end face 15 is parallel to the first surface 25. Each first end face 15 may be flush with the first surface 25.

The second cladding layer 13 is provided on the first cladding layer 11 and the core layers 12. The second cladding layer 13 covers the core layers 12. The material of the second cladding layer 13 is, for example, organic resin such as epoxy resin or polyimide resin. The thickness of the second cladding layer 13 is, for example, approximately 10 μm to approximately 30 μm.

According to the optical waveguide 10, the refractive index of the core layers 12 is higher than the refractive index of each of the first cladding layer 11 and the second cladding layer 13.

The optical semiconductor chip 40 includes optical devices (not depicted in the drawings) and is flip-chip mounted on the substrate 30. The optical semiconductor chip 40 is provided on the principal surface 31. The optical semiconductor chip 40 is positioned on one side of the optical waveguide 10 in the extension (longitudinal) direction of the core layers 12 with the optical devices being optically coupled to the optical waveguide 10. The optical devices may be either photodetectors or light emitters. There may be a step between where the first support member 20 is provided and where the optical semiconductor chip 40 is provided in the principal surface 31.

The optical connector 50 includes optical fibers 60, a second support member 70, and protrusions 76.

The second support member 70 is formed of, for example, glass. For example, the second support member 70 is a glass block. The second support member 70 is detachably attached to the first support member 20. The second support member 70 has a second surface 75 that faces the first surface 25 of the first support member 20. The first surface 25 and the second surface 75 may be in direct contact with each other.

The optical fibers 60 are supported by the second support member 70. The optical fibers 60 each include cladding 61 and a core 62. The core 62 has a second end face 65 exposed on the second surface 75. For example, the second end face 65 may be parallel to the second surface 75. The second end face 65 may be flush with the second surface 75. The second end face 65 faces its corresponding first end face 15. The first end face 15 and its corresponding second end face 65 may be in direct contact with each other. The side surfaces of each core 62 are covered with the cladding 61. The core 62 is an example of “second core.”

The protrusions 76 are provided on the second surface 75. Each protrusion 76 fits into its corresponding recess 26. The protrusions 76 each have a truncated cone shape. The diameter of each protrusion 76 is continuously reduced toward its top end. For example, the protrusions 76 each have a wall face that is inclined at approximately 7° from an axis vertical to the second surface 75. The diameter of each protrusion 76 at the second surface 75 is, for example, 30 μm to 200 μm. The height of each protrusion 76 is, for example, 30 μm to 200 μm.

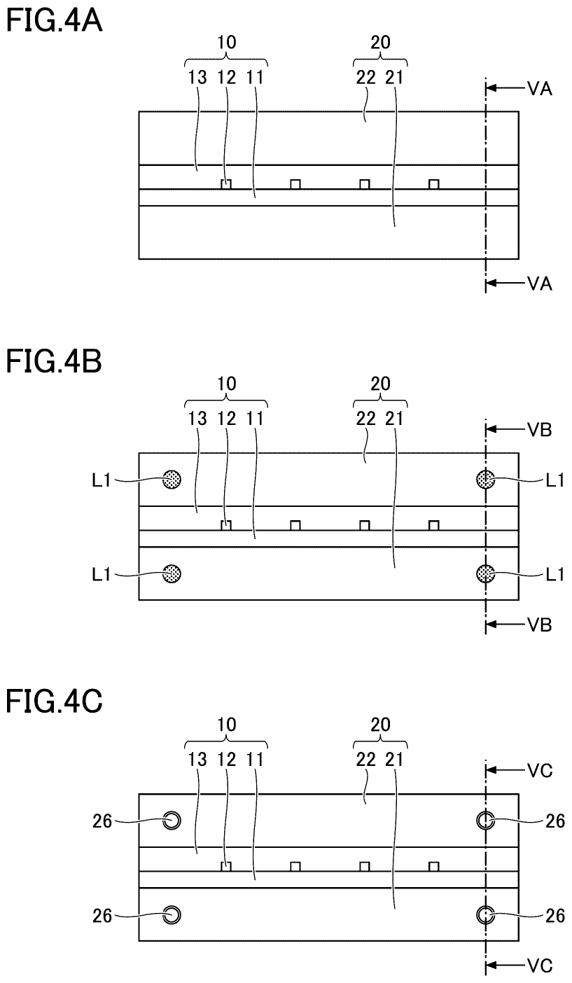

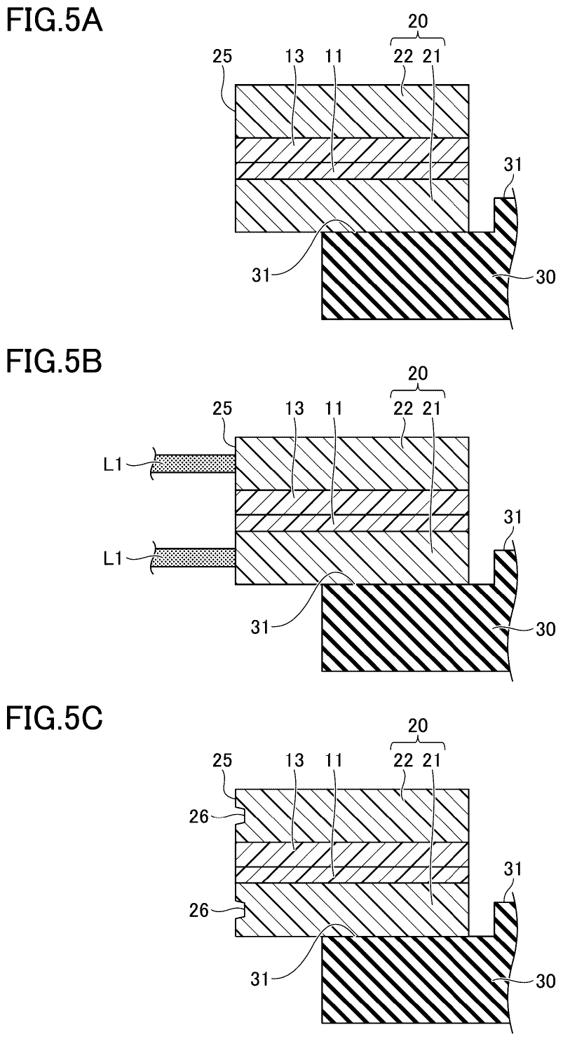

Next, a method of forming the recesses 26 is described. FIGS. 4A through 4C are side views of the optical waveguide 10 and the first support member 20, illustrating a method of forming the recesses 26. FIGS. 5A through 5C are sectional views of the optical waveguide 10 and the first support member 20, taken along the line VA-VA of FIG. 4A, the line VB-VB of FIG. 4B, and the line VC-VC of FIG. 4C, respectively, illustrating a method of forming the recesses 26.

Referring to FIGS. 4A and 5A, the first part 21, the first cladding layer 11, the core layers 12, the second cladding layer 13, and the second part 22 are formed on the principal surface 31 of the substrate 30. The optical semiconductor chip 40 may be flip-chip mounted on the substrate 30 before the formation of the first part 21, the first cladding layer 11, the core layers 12, the second cladding layer 13, and the second part 22.

Next, referring to FIGS. 4B and 5B, excimer laser light L1 is emitted onto areas where the recesses 26 are to be formed on the first surface 25. To emit the excimer laser light L1, alignment is performed using the core layers 12 as a reference.

Referring to FIGS. 4C and 5C, the areas exposed to the excimer laser light L1 are removed from the first part 21 and the second part 22, so that the recesses 26 are formed in the first surface 25.

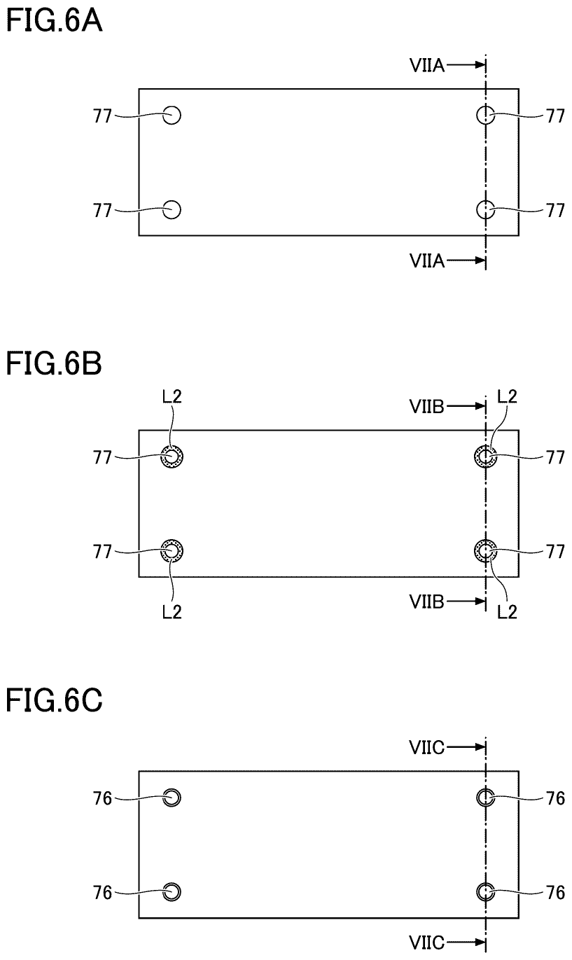

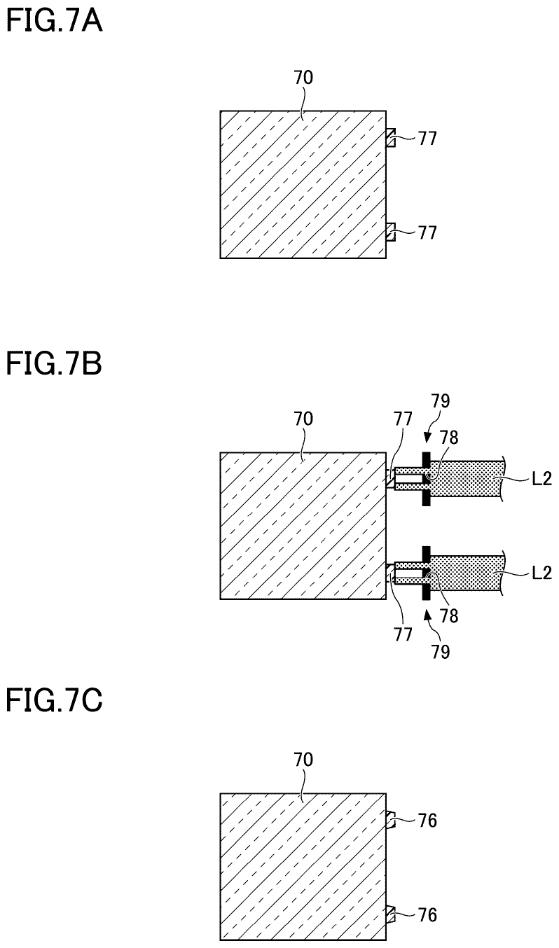

Next, a method of forming the protrusions 76 is described. FIGS. 6A through 6C are side views of the second support member 70, illustrating a method of forming the protrusions 76. FIGS. 7A through 7C are sectional views of the second support member 70, taken along the line VIIA-VIIA of FIG. 6A, the line VIIB-VIIB of FIG. 6B, and the line VIIC-VIIC of FIG. 6C, respectively, illustrating a method of forming the protrusions 76.

Referring to FIGS. 6A and 7A, the optical connector 50, into which the optical fibers 60 and the second support member 70 are integrated without the protrusions 76 being formed, is prepared. Next, a photosensitive resin film is formed, exposed to light, and developed to form cylindrical protrusions 77 in areas where the protrusions 76 are to be formed on the second surface 75.

Next, referring to FIGS. 6B and 7B, excimer laser light L2 is emitted to the respective perimeters of the protrusions 77 through a mask 79 in which annular openings 78 are formed. To emit the excimer laser light L2, alignment is performed using the cores 62 of the optical fibers 60 as a reference.

Referring to FIGS. 6C and 7C, the areas exposed to the excimer laser light L2 are removed from the protrusions 77, so that the protrusions 76 are formed on the second surface 75.

The optical waveguide component 1 is used with the first support member 20 and the second support member 70 being coupled to each other. To couple the first support member 20 and the second support member 70, the first surface 25 and the second surface 75 are positioned to face each other, and each protrusion 76 is fitted into its corresponding recess 26. Then, the second support member 70 is fixed to the first support member 20. The second support member 70 may be removably fixed to the first support member 20 using, for example, a latch mechanism.

According to the optical waveguide component 1, fitting each protrusion 76 into its corresponding recess 26 facilitates alignment between the optical waveguide 10 and the optical fibers 60. For example, it is possible to align the optical waveguide 10 with the optical fibers 60 with an accuracy of within 4 μm.

Furthermore, when the first end faces 15 and the second end faces 65 are in direct contact with each other, transmission loss can be kept low between the optical waveguide 10 and the optical fibers 60. The first end faces 15 and the second end faces 65, however, do not have to be in direct contact with each other. For example, the second end faces 65 may be depressed relative to the first surface 25.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

What is claimed is:

1. An optical waveguide component comprising:
a first support member having a first surface, the first surface including a plurality of recesses; and
an optical waveguide supported by the first support member, the optical waveguide including a first core, the first core having a first end face exposed on the first surface.

2. The optical waveguide component as claimed in claim 1, wherein the first support member is formed of organic resin.

3. The optical waveguide component as claimed in claim 1, wherein a diameter of each of the plurality of recesses is continuously reduced toward a bottom of said each of the plurality of recesses.

4. The optical waveguide component as claimed in claim 1, wherein the optical waveguide is a polymer waveguide.

5. The optical waveguide component as claimed in claim 1, further comprising:
an optical connector, the optical connector including
a second support member detachably attached to the first support member, the second support member having a second surface facing the first surface;
an optical fiber supported by the second support member, the optical fiber including a second core, the second core having a second end face exposed on the second surface, the second end face facing the first end face; and
a plurality of protrusions on the second surface, the plurality of protrusions being fitted into the plurality of recesses.

6. The optical waveguide component as claimed in claim 5, wherein the second end face is in direct contact with the first end face.

7. The optical waveguide component as claimed in claim 5, wherein a diameter of each of the plurality of protrusions is continuously reduced toward a top end of said each of the plurality of protrusions.

8. The optical waveguide component as claimed in claim 5, wherein the second support member is formed of glass.

9. The optical waveguide component as claimed in claim 1, further comprising:
a substrate to which the first support member is fixed; and
an optical semiconductor chip mounted on the substrate and optically coupled to the optical waveguide.

10. The optical waveguide component as claimed in claim 1, further comprising:
a substrate to which the first support member is fixed,
wherein the first support member includes a first part and a second part between which the optical waveguide is sandwiched, the first support member being fixed to a surface of the substrate, and
the plurality of recesses include a plurality of first recesses formed in the first part and a plurality of second recesses formed in the second part.

11. The optical waveguide component as claimed in claim 10, wherein
the plurality of first recesses are aligned parallel to the surface of the substrate, and
the plurality of second recesses are aligned parallel to the surface of the substrate.

12. The optical waveguide component as claimed in claim 11, wherein
one of the plurality of first recesses and one of the plurality of second recesses are aligned perpendicular to the surface of the substrate, and
another one of the plurality of first recesses and another one of the plurality of second recesses are aligned perpendicular to the surface of the substrate.

13. The optical waveguide component as claimed in claim 10, further comprising:
an optical semiconductor chip mounted on the surface of the substrate and optically coupled to the optical waveguide, and
the surface of the substrate includes a step between where the first part is fixed and where the optical semiconductor chip is mounted.

14. The optical waveguide component as claimed in claim 1, wherein
a diameter of each of the plurality of recesses at the first surface is 30 μm to 200 μm.

15. The optical waveguide component as claimed in claim 1, wherein
a depth of each of the plurality of recesses relative to the first surface is 30 μm to 200 μm.
